(19) United States
(12) Patent Application Publication
(10) Pub. No.: US 2026/0033373 A1
(43) Pub. Date: Jan. 29, 2026

(54) METHOD FOR THE MASS PRODUCTION OF ELECTRONIC DEVICES INCORPORATING PROTECTION ELEMENTS, AND RESULTING ELECTRONIC DEVICES

(71) Applicant: STMicroelectronics International N.V., Geneva (CH)

(72) Inventor: Jean-Michel RIVIERE, Froges (FR)

(73) Assignee: STMicroelectronics International N.V., Geneva (CH)

(21) Appl. No.: 19/282,230

(22) Filed: Jul. 28, 2025

(30) Foreign Application Priority Data
Jul. 29, 2024 (FR) FR2408400

(51) Int. Cl. H01L 21/52

(52) U.S. Cl. CPC H01L 21/52

(57) ABSTRACT

A method for producing electronic devices includes attaching a protective grid to a first substrate, where the grid includes a set of patterns each associated with a device. Walls are molded on the first substrate to form at least one set of peripheral walls of the devices. A set structure including the first substrate, the grid and the walls is attached to a second substrate. An assembly formed by the set structure and the second substrate is cut, depending on the peripheral walls, into individual devices. When attaching the grid to the first substrate, an electrical contact is established between each pattern and an element of the first substrate. Attaching the set structure to the second substrate includes establishing an electrical contact between each pattern and an element of the second substrate.

### PRIORITY CLAIM

This application claims the priority benefit of French Application for Patent No. FR2408400, filed on Jul. 29, 2024, the content of which is hereby incorporated by reference in its entirety to the maximum extent allowable by law.

### TECHNICAL FIELD

Embodiments herein relate to the field of microelectronics and, more specifically, the field of producing electronic devices comprising electronic chips, in particular electronic chips including integrated optical elements for emitting and/or receiving light.

### BACKGROUND

Known electronic devices comprise a support substrate including a network of electrical connections, one or more electronic chips, for example a light-emitting electronic chip and a light-receiving electronic chip, mounted, remotely, above a face of the support substrate, and a closure substrate (or encapsulation cover) mounted on said face of the support substrate and delimiting one or more chambers in which electronic chips are located, this encapsulation cover having, where appropriate, openings opposite the optical elements of the electronic chips in which optical components such as lenses and/or light filters are generally provided.

Furthermore, some electronic devices require specific elements, such as protection against electromagnetic radiation, also called electromagnetic shields, or protection against mechanical failures, for example to deactivate a laser diode if an optical component such as a lens or a filter associated with this diode becomes detached from its support or breaks. As these elements are often difficult to implement, they generally require the unit production of electronic devices.

There is therefore a need to integrate protection elements in electronic devices, enabling the mass production thereof.

### SUMMARY

In an embodiment, a method for producing electronic devices, comprises: attaching a protective grid to a first substrate, the protective grid being made of an electrically conductive material and comprising a set of patterns, each pattern being associated with an electronic device and comprising at least one part, a component of which extends in a direction perpendicular to the first substrate; molding walls on the first substrate, the molded walls forming at least a set of peripheral walls of said electronic devices; attaching, to a second substrate, a set structure comprising the first substrate, the protective grid and the molded walls; and cutting, according to the peripheral walls, an assembly comprising the set structure and the second substrate into a plurality of electronic devices. The step of attaching the protective grid to the first substrate comprises: establishing an electrical contact between each pattern of the protective grid and at least one element of the first substrate and/or attaching, to the second substrate, the set structure comprising the first substrate, the protective grid and the molded walls comprising establishing an electrical contact between each pattern of the protective grid and at least one element of the second substrate.

Such a method makes it possible, in particular, to improve the methods of production of electronic devices, enabling plate production of a plurality of electronic devices.

According to embodiments, the molded walls comprise at least one portion of the part of the protective grid, a component of which extends in a direction perpendicular to the first substrate, thereby protecting this part of the protective grid and limiting the risks of undesired electrical contact.

According to other embodiments, the protective grid forms a peripheral structure for each of said electronic devices, the peripheral walls being molded on said peripheral structures, thereby protecting the electronic devices from electromagnetic waves.

According to other embodiments, the method comprises establishing an electrical contact between the protective grid and at least one element of each of the first and second substrates.

According to other embodiments, one of said first and second substrates comprises openings, the method also comprising attaching lenses and/or filters to said openings, the other of said first and second substrates comprising electronic circuits placed opposite said lenses and/or filters.

According to other embodiments, the protective grid is electrically connected to said electric circuits and to said lenses and/or filters and designed to enable the detection, after cutting, of movement or breakage of a lens and/or filter.

According to other embodiments, walls are molded on at least part of the protective grid extending in a plane parallel to the first substrate.

According to other embodiments, the protective grid is attached to the first substrate by bonding and/or according to which the set structure comprising the first substrate, the protective grid and the molded walls is attached to the second substrate by bonding.

According to other embodiments, the protective grid is obtained by a press-forming or stamping method.

According to another aspect, an electronic device obtained by the aforementioned method is proposed. This electronic device has the advantage in particular of being able to be mass produced.

### BRIEF DESCRIPTION OF THE DRAWINGS

Other advantages and features will become apparent upon examining the detailed description of non-limiting embodiments and implementations, and from the appended drawings, wherein:

FIG. 1 schematically shows a set of electronic devices produced simultaneously;

FIGS. 2 and 3 show steps in a method for the production of electronic devices;

FIGS. 4A and 4B show a first exemplary protective grid in a view from above and a view from the side, respectively;

FIGS. 5A-5D show in cross-section steps for producing a set of electronic devices;

FIG. 6 shows a second example of a step for molding walls;

FIG. 7 shows a second exemplary protective grid, viewed in perspective; and

FIGS. 8A-8C show in cross-section steps for producing a set of electronic devices.

### DETAILED DESCRIPTION

According to embodiments, a protective grid comprising a protective pattern for each electronic device of a set of electronic devices is attached to a first substrate used to produce this set of electronic devices. After walls, in particular peripheral walls, have been molded, the set structure comprising the first substrate, the protective grid and the molded walls is attached to a second substrate. This last set is then cut to form the electronic devices.

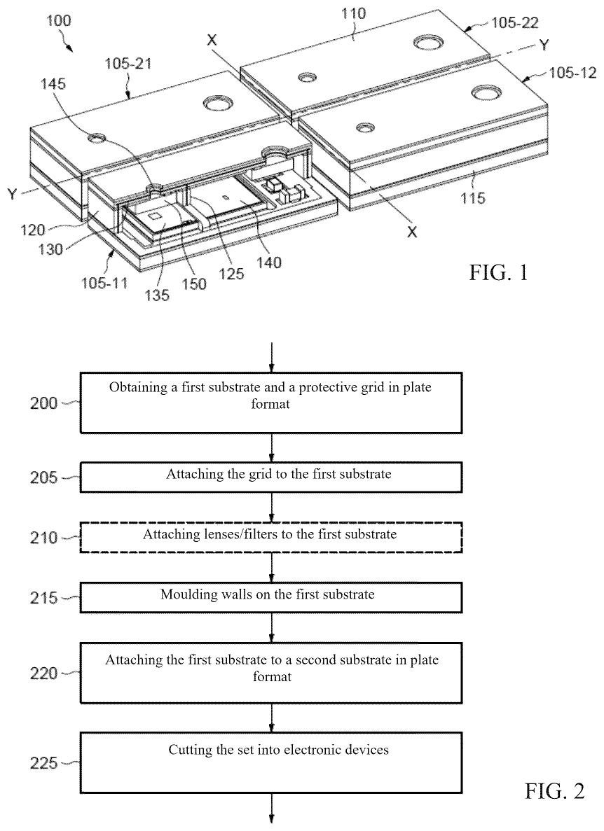

FIG. 1 schematically shows a set of electronic devices produced simultaneously according to embodiments, partially cut away to show part of the inside of an electronic device. The set 100 of electronic devices, forming a plate, comprise in this case four electronic devices 105-11, 105-12, 105-21 and 105-22. For the sake of clarity, the plate is shown here after cutting and obtaining the four electronic devices 105-11, 105-12, 105-21 and 105-22. Of course, the set of electronic devices can comprise a very large number of electronic devices, for example a plate of X by Y electronic devices. All of the electronic devices of the plate are produced simultaneously, the plate then being cut (in this case along the X-X axis and the Y-Y axis) to produce the four electronic devices.

As shown, the plate 100 comprises in this case a first substrate 110, or closure substrate or encapsulation cover, and a second substrate 115, or support substrate. The two substrates are connected to one another here by walls, in particular peripheral walls of the electronic devices, for example the peripheral wall 120 of the electronic device 105-11, and, where appropriate, inner walls, for example the inner wall 125 of the electronic device 105-11. The walls can be made by molding and are preferably made of an opaque material, in particular when the electronic device comprises a light emitter and/or receiver.

The walls, or certain walls, can comprise part of a protection grid, in this case the protection grid 130. As this is electrically conductive and can be connected to the electric circuit of the electronic devices, it can form an electromagnetic shield.

Furthermore, the walls form one or more chambers in each electronic device, housing one or more electronic chips, for example the electronic chips 135 and 140, attached in this case to the support substrate 115 which comprises electric tracks to exchange electrical signals between the chips and/or to or from the outside of the electronic device. If the electronic chips are light emitters and/or receivers (in this case the electronic chip 135 is a light emitter and the electronic chip 140 is a light receiver), openings are made in the closure substrate, opposite the emitter and receiver. An optical component such as a lens and/or filter is preferably placed under the opening to protect the inside of the electronic device and control the light emitted or received. By way of example, the closure substrate 110 comprises the opening 145 located opposite the emitter 135, to which the lens 150 is attached.

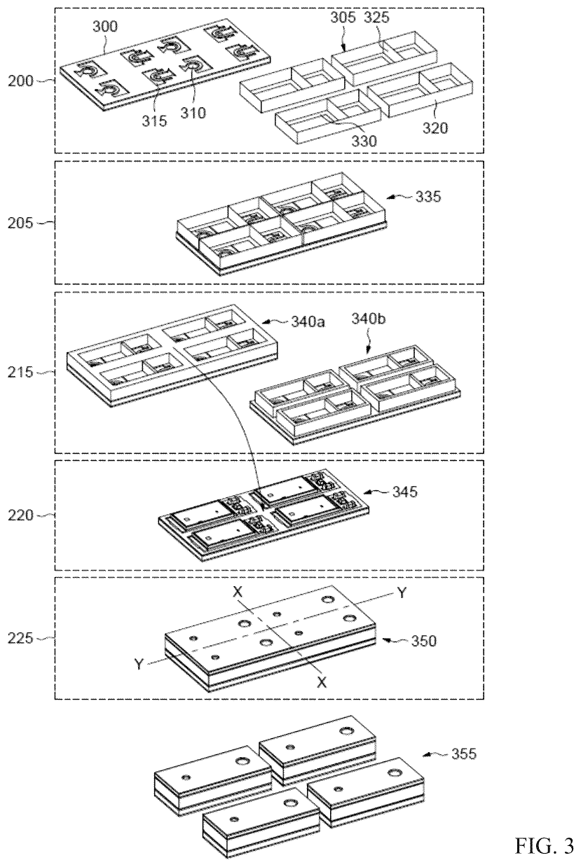

FIGS. 2 and 3 show an example of steps in a method for the production of electronic devices according to embodiments. As shown, the objective of a first step (step 200) is in this case to obtain a first substrate 300, for example a closure substrate, and a protective grid 305. The first substrate and protective grid are obtained here in the form of a plate, enabling a set of electronic devices to be produced.

According to embodiments, the first substrate is made of laminate epoxy. It can also comprise a plurality of layers stacked and laminated together. The first substrate can be machined, for example, to include openings such as the openings 310 to let light through. It can also comprise open cavities such as the open cavities 315, formed next to the openings, allowing adhesive to be applied and lenses to be bonded at the openings, without creating any excess thickness due to the adhesive.

The protective grid is, for example, a thin plate, for example made of copper or brass, pressed or stamped to form a 3D structure, the shape of which is determined according to the desired patterns to form an electromagnetic shield, allow light to pass through with respect to the light emitter and/or receiver, connect an element of the protective substrate to an element of the support substrate, etc. According to embodiments and as shown in FIG. 3, the protective grid 305 comprises, for each electronic device, a peripheral element 320, a component of which extends in a plane substantially perpendicular to the first substrate (i.e., the peripheral element is not parallel to the first substrate) and forming a continuous or discontinuous perimeter structure (or side shields), one or more elements 325, of which a component preferably extends along a plane substantially perpendicular to the first substrate and forming an inner structure (or inner shields), and/or one or more elements 330 preferably extending along a plane substantially parallel to the first substrate and forming an upper structure (or upper shield, referred to as such as it is located above the electronic chip(s) in the electronic devices). When the protective grid is attached to the first substrate, the upper shield is against (or close to) the first substrate and can protect electronic chips located below it. According to other embodiments, the protective grid 305 comprises, for each electronic device, only a side shield, an inner shield or an upper shield or comprises any combination of these shields.

In a subsequent step (step 205), the protective grid is attached to the first substrate, according to a predefined position, to form a set 335. According to embodiments, the protective grid is bonded to the first substrate, for example with a standard adhesive such as the adhesive known under the reference Loctite Ablestik 8387B. Still by way of example, bonding can comprise depositing an adhesive film on the first substrate, at locations where the protective grid will be in contact with the first substrate (e.g., the part forming the upper shield), positioning the protective grid on the first substrate then warming up the set to enable the adhesive to polymerize.

According to other embodiments, attaching the protective grid to the first substrate comprises establishing an electrical contact between the protective grid and conductive elements of the first substrate, for example establishing an electrical contact between a point on the protective grid and a conductive surface or track present on the surface of the first substrate, for each electronic device. A conductive adhesive can be used for such purposes.

According to other embodiments and if the electronic devices comprise light emitters and/or receivers, optical components such as lenses and/or filters can be attached to the first substrate (step 210), for example at the openings 310. For this purpose, adhesive such as that used to bond the protective grid can be deposited near the openings, for example in the open cavities 315. The lenses and/or filters can then be positioned, and the set can be warmed up to enable the adhesive to polymerize. It has been observed that the polymerization of the adhesive can be carried out at the same time for the protective grid and the lenses and/or filters, or separately. According to other embodiments, the lenses and/or filters are attached in a subsequent step, for example after the walls have been molded.

Walls are then molded on the first substrate (step 215). The molded walls comprise the peripheral walls of the electronic devices (e.g., the wall 120 shown in FIG. 1) and, optionally, inner walls (e.g., the wall 125 shown in FIG. 1). Molding can be carried out in a conventional manner, using a mold and a liquid or viscous polymeric material, for example an epoxy resin-based material, by way of example, a material such as the compounds known under the reference NITTO NT-8560 TDS or under the reference Tecoré 820L-B or TC-8020LA-7000. This material is preferably opaque, in particular when the electronic devices comprise one or more light emitters and/or receivers. According to embodiments, the walls comprise at least part of the protective grid, for example side shields 320, inner shields 325 and/or upper shields 330.

The peripheral walls of an electronic device can be molded with part of the peripheral walls of the adjacent electronic devices (these walls then being cut in thickness to separate the electronic devices), as shown with reference numeral 340a, or can be separate, as shown with reference numeral 340b.

According to other embodiments, the walls are added or created by another method.

The set structure 340a or 340b, comprising the first substrate, the protective grid, where appropriate lenses or filters and the walls, is then mounted on a second substrate (step 220), for example a support substrate 345 on which the electronic chips of the electronic devices are mounted. The second substrate comprises, in this case, a plurality of layers stacked and laminated together, in which conductive tracks are formed to enable the exchange of signals between electronic chips of each electronic device and between an electronic chip of an electronic device and an outside element. Like the first substrate, the second substrate is obtained in the form of a plate, enabling a set of electronic devices to be produced.

Mounting the second substrate with the set structure comprising the first substrate, the protective grid and the walls can be carried out by bonding. Bonding can comprise depositing an adhesive film on the second substrate, for example at locations where the molded walls will be in contact with the second substrate, positioning the set structure comprising the first substrate, the protective grid and the walls on the second substrate then warming up the set to enable the adhesive to polymerize. Once again, the adhesive used can be the adhesive known under the reference Loctite Ablestik 8387B.

According to embodiments, attaching the second substrate to the set structure comprising the first substrate, the protective grid and the walls comprises establishing an electrical contact between the protective grid and conductive elements of the second substrate, for example establishing an electrical contact between a point on the protective grid and a conductive surface or track present on the surface of the second substrate, for each electronic device. These conductive surfaces or tracks are in this case connected to ground to enable portions of the protective grid to perform a role of electromagnetic shield. Contact is established, for example, using a conductive adhesive.

In a subsequent step (step 225), an assembly 350 comprising the set structure 24 (with the first substrate) and the second substrate is cut to obtain the electronic devices 255. Cutting is carried out depending on the peripheral walls. Cutting is carried out, for example, using a cutting disc.

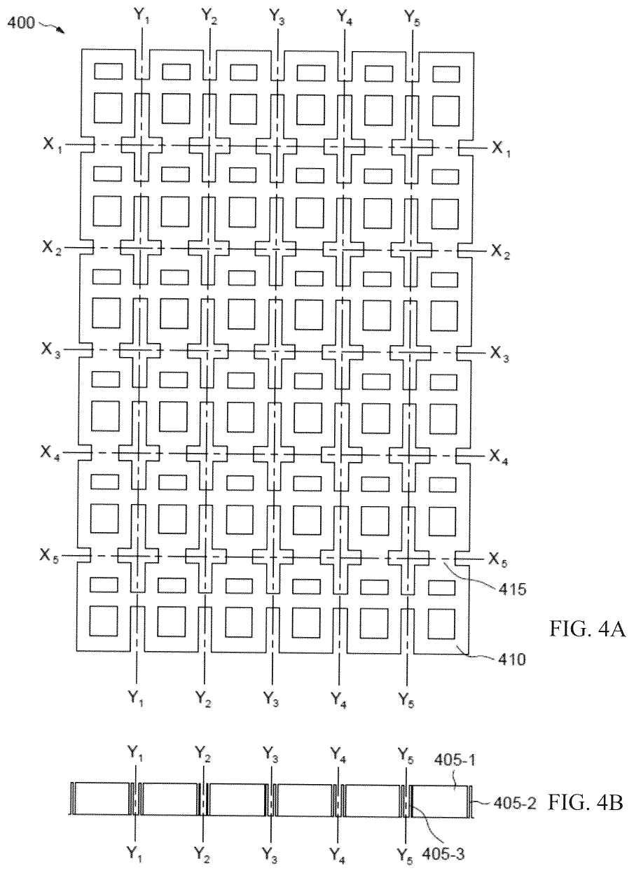

FIGS. 4A and 4B show a first exemplary protective grid in a view from above and a view from the side, respectively.

After the protective grid 400 has been attached to a first substrate and this set has been joined to a second substrate, the new set is cut along the axes X₁ to X₅ and Y₁ to Y₆ to form 36 electronic devices.

By way of example, the protective grid comprises a set of patterns organized in the form of a matrix, each pattern corresponding to a specific electronic device. Each pattern comprises a three-dimensional shape determined by its function. For example, the pattern located in the first row and sixth column of the matrix comprises in this case four side shields (only the side shields 405-1, 405-2 and 405-3 are shown), an inner shield (not shown) and an upper shield 410. These shields provide electromagnetic protection to electronic chips located between these shields. They can also provide an electrical contact between substrate elements located on either side of this pattern, for example to provide a common ground. Of course, other pattern forms can be used.

A shown, each pattern is connected here to another pattern by one or more connecting elements with generic reference numeral 415 which are cut when the electronic devices are separated from one another.

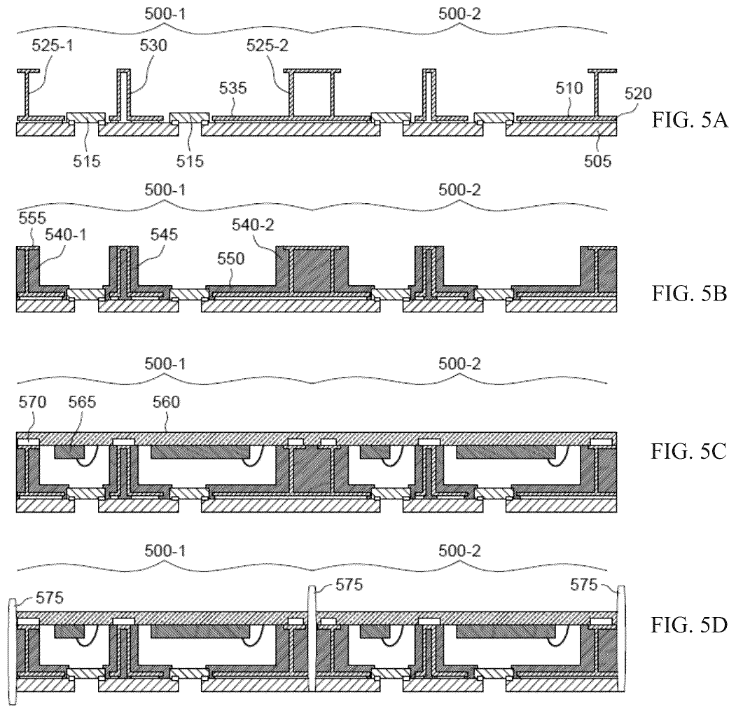

FIGS. 5A-5D show a first example of certain steps for producing a set structure comprising a closure substrate, a protective grid and walls, viewed in cross-section.

For the sake of clarity, only one portion of this set, corresponding to two electronic devices, is shown, as illustrated with reference numerals 500-1 and 500-2.

FIG. 5A shows the set after attachment, to a substrate 505, of a protective grid 510 and lenses with generic reference numeral 515, using an adhesive layer 520 deposited at appropriate locations.

As shown, the protective grid 510 comprises, in the portion 500-1, side shields 525-1 and 525-2 (the others are not shown in the sectional view), an inner shield 530 and an upper shield 535 bonded to the substrate 505. The side shield 525-1, the inner shield 530 and the upper shield 535 form a first cavity designed to protect one or more electronic chips, for example a light emitter. Similarly, the side shield 525-2, the inner shield 530 and the upper shield 535 form a second cavity designed to protect one or more electronic chips, for example a light receiver.

FIG. 5B shows the set, after the walls have been molded. As shown, the walls are molded here on the side, inner and upper shields. Thus, for example, the peripheral walls 540-1 and 540-2 are molded on the side shields 525-1 and 525-2, respectively, the inner wall 545 is molded on the inner shield 530 and molding 550 also takes place on the upper wall 535 and, here, on the edge of the lenses.

According to the example shown, molding does not extend over the whole of the part of the protective grid located opposite the substrate, in particular over the part with reference numeral 555, to enable an electrical contact to be established between the protective grid and a support substrate to which the set would be attached.

FIG. 5C shows the set structure comprising the substrate, the protective grid and the walls being joined to another substrate 560, for example by bonding, as described above. The latter comprises electronic chips with generic reference numeral 565 connected to tacks (not shown) of this substrate and contacts with generic reference numeral 570 designed to enable an electrical contact to be established with the protective grid.

FIG. 5D shows the set during cutting, to separate the electronic devices from one another using a cutting device with generic reference numeral 575, for example a cutting disc.

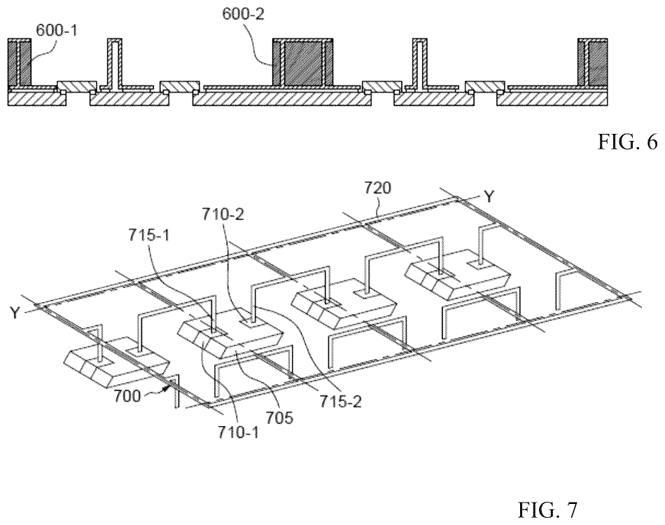

FIG. 6 shows a second example of a step for molding walls during the production of a set structure comprising a closure substrate, a protective grid and walls, viewed in cross-section. The step shown in FIG. 6 is an alternative to the step shown in FIG. 5B.

As shown, the peripheral walls such as the peripheral walls 600-1 and 600-2 are molded on the side shields, for example the side shields 525-1 and 525-2, respectively, however, no inner wall is molded on the inner shields, for example on the inner shield 530, and no molding takes place on the upper walls, for example the upper wall 535, or on the edge of the lenses.

FIG. 7 shows a second exemplary protective grid, viewed in perspective.

The protective grid 700 shown in FIG. 7 is used in particular to detect movement or breakage of a lens or filter, for example movement or breakage of a diffuser filter placed in front of a laser transmitter. For this purpose, the protective grid comprises connection elements for establishing electrical contacts between elements of a first substrate, for example an electrical contact of a lens attached to the first substrate, and an element of a second substrate, for example a contact connected to an electric track of the second substrate.

The protective grid also comprises connecting elements for holding the connection elements in predefined relative positions while the protective grid is fixed to a substrate and walls are molded. At least some connecting elements are partially modified when the final set is cut into electronic devices to enable the required electrical connections to be established.

By way of example, the protective grid 700 can be designed to control the position of the lens 705 comprising the electrical contacts 710-1 and 710-2. For this purpose, the protective grid 700 comprises the connection elements 715-1 and 715-2 to establish an electrical contact between the electrical contacts 710-1 and 710-2 and electrical contacts of elements of a substrate (not shown) joined to a substrate (not shown) to which the protective grid 700 and lens 705 are attached. Furthermore, the protective grid comprises the connecting element 720 which is used to hold the connection elements 715-1 and 715-2 when the electronic devices are being produced. As shown by the dashed line Y-Y, the connecting element 720 is separated from the connection elements 715-1 and 715-2 during the final cutting into electronic devices.

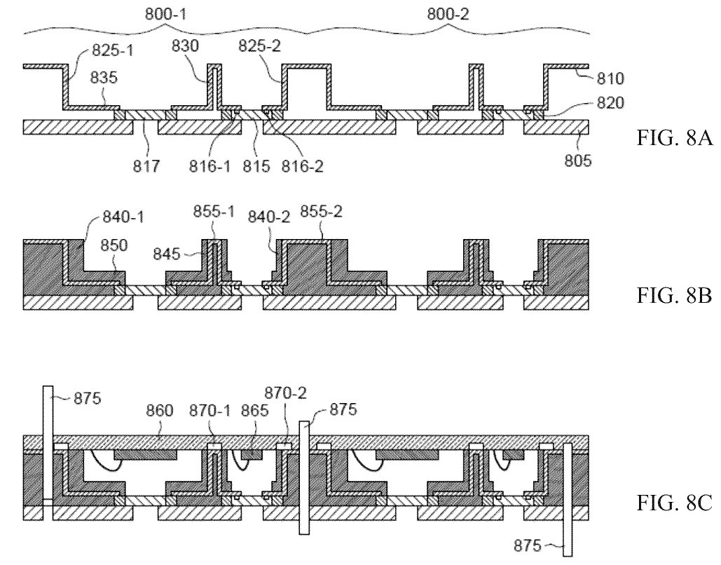

FIGS. 8A-8C show a second example of certain steps for producing a set structure comprising a closure substrate, a protective grid and walls, viewed in cross-section.

For the sake of clarity, only one portion of this set, corresponding to two electronic devices, is shown, as illustrated with reference numerals 800-1 and 800-2.

FIG. 8A shows the set after attachment, to a substrate 805, of a protective grid 810 and lenses and/or filters with generic reference numeral 815 and 817, using an adhesive layer 820 deposited at appropriate locations.

The lenses and/or filters 815 are, in this case, lenses and/or filters placed in front of light emitters, for example laser transmitters, whose position needs to be monitored, while the lenses and/or filters 817 are, in this case, lenses placed in front of light receivers, for example laser receivers, whose position does not need to be monitored.

As shown, the protective grid 810 comprises, in the portion 800-1, side shields 825-1 and 825-2 (the others are not shown in the sectional view), an inner shield 830 and an upper shield 835 bonded to the substrate 805. The side shield 825-1, the inner shield 830 and the upper shield 835 form a first cavity designed to protect one or more electronic chips, in particular, in this case, a light transmitter. Similarly, the side shield 825-2, the inner shield 830 and the upper shield 835 form a second cavity designed to protect one or more electronic chips, in particular, in this case, a light receiver.

As shown as well, a first electrical contact 816-1 of the lens 815 is electrically connected to the inner wall 830 and a second electrical contact 816-2 of the lens 815 is electrically connected to the side wall 825-2. Electrical contacts can, for example, be established by simple pressing or bonding, using a conductive adhesive.

FIG. 8B shows the set, after the walls have been molded. As shown, the walls are molded here on the side, inner and upper shields. Thus, for example, the peripheral walls 840-1 and 840-2 are molded on the side shields 825-1 and 825-2, respectively, the inner wall 845 is molded on the inner shield 830 and molding 850 also takes place on the upper wall 835.

According to the example shown, molding does not extend over the whole of the part of the protective grid located opposite the substrate, in particular over the parts with reference numerals 855-1 and 855-2, to enable an electrical connection to be established between the electrical contacts 816-1 and 816-2 and elements of a substrate to which the set shown in FIG. 8b would be attached.

FIG. 8C shows the set structure comprising the substrate, the protective grid and the walls being joined to another substrate 860, for example by bonding, as described above. The latter comprises electronic chips, in particular a light emitter 865 such as a laser transmitter, connected to tracks (not shown) of this substrate, and contacts, in particular the contacts 870-1 and 870-2 designed to enable an electrical contact to be established with the electrical contacts 816-1 and 816-2 through the protective grid. Once again, electrical contacts can, for example, be established by simple pressing or bonding, using a conductive adhesive.

As shown, the electronic devices can then be separated from one another using a cutting device with generic reference numeral 875, for example a cutting disc.

Of course, if the examples shown in FIGS. 6 and 7 relate to the monitoring of the position of lenses and/or filters, the systems and methods described are applicable to other elements, at least one feature of which has to be monitored using an electrical signal.

1. A method for producing electronic devices, comprising:
attaching a protective grid to a first substrate, the protective grid being made of an electrically conductive material and comprising a set of patterns, each pattern of the set of patterns being associated with an electronic device and comprising at least one part having a component which extends in a direction perpendicular to the first substrate;
wherein attaching the protective grid to the first substrate comprises establishing an electrical contact between each pattern of the protective grid and at least one element of the first substrate;
molding walls on the first substrate, the molded walls forming at least a set of peripheral walls of said electronic devices;
attaching a set structure to a second substrate, the set structure comprising the first substrate, the protective grid and the molded walls;
wherein attaching the set structure to the second substrate comprises establishing an electrical contact between each pattern of the protective grid and at least one element of the second substrate; and
cutting, according to the peripheral walls, an assembly comprising the set structure attached to the second substrate into a plurality of electronic devices.

2. The method according to claim 1, wherein the molded walls comprise at least one portion of the part of the protective grid, a component of which extends in a direction perpendicular to the first substrate.

3. The method according to claim 1, wherein the protective grid forms a peripheral structure for each of said electronic devices, the peripheral walls being molded on said peripheral structures.

4. The method according to claim 1, further comprising establishing an electrical contact between the protective grid and at least one element of each of the first and second substrates.

5. The method according to claim 4, wherein one of said first and second substrates comprises openings, the method further comprising attaching optical components selected from lenses and filters to said openings, the other of said first and second substrates comprising electronic circuits placed opposite said optical components.

6. The method according to claim 5, wherein the protective grid is electrically connected to said electric circuits and to said optical components and designed to enable the detection, after cutting, of optical component movement or breakage.

7. The method according to claim 1, wherein walls are molded on at least part of the protective grid extending in a plane parallel to the first substrate.

8. The method according to claim 1, wherein the protective grid is attached to the first substrate by bonding and/or according to which the set structure comprising the first substrate, the protective grid and the molded walls is attached to the second substrate by bonding.

9. The method according to claim 1, wherein the protective grid is obtained by a press-forming or stamping method.

10. An electronic device obtained by the method according to claim 1.
